(19) United States
(12) Patent Application Publication
(10) Pub. No.: US 2024/0057248 A1
(43) Pub. Date: Feb. 15, 2024

(54) PCB DESIGN PROCESSES

(71) Applicant: Darryl Zawada, Columbia, MD (US)

(72) Inventor: Darryl Zawada, Columbia, MD (US)

(21) Appl. No.: 17/818,446

(22) Filed: Aug. 9, 2022

(51) Int. Cl. H05K 1/02

(52) U.S. Cl. CPC H05K 1/0269

(57) ABSTRACT

A silkscreen layer of a printed circuit board is herein disclosed. The silkscreen layer includes PCB elements and polarity markings thereon. Each polarity marking is formed from a first end line segment, a middle line segment perpendicularly connected to the first end line segment, and a second end line segment perpendicularly connected to the middle line segment. In use, each polarity marking indicates a polarity of a respective PCB element of the plurality of PCB elements and the plurality of polarity markings are the only polarity markings on the silkscreen layer. Further disclosed is a method of removing the impedance requirement from a PCB design.

### BACKGROUND OF THE INVENTION

The present invention relates to printed circuit boards and, more particularly, to a printed circuit board (PCB) design process that reduces costs and cycle time.

The present invention addresses issues related to polarity markings on PCBs and impedance-controlled requirements. As shown in FIG. 2, prior to the present invention, prior polarity markings 14 on a PCB 12 are inconsistent and unusable without manual editing. For example, some are plus signs, some are straight lines, and some are lines with arrow directions added.

Further, certain other approaches had many pitfalls. A single-line polarity markings approach to polarity markings lacks clarity. A solid and dashed line polarity markings approach differentiates from different component types (e.g., diodes and capacitors), rendering the silkscreen layer overly complex.

As can be seen, there is a need for an improved process for designing PCBs. The strategies discussed herein are universal to any entity or individual that designs PCBs and alleviates the need for any editing of the silkscreen on the PCB.

### SUMMARY OF THE INVENTION

In one aspect of the present invention, a silkscreen layer of a printed circuit board (PCB) is disclosed, the silkscreen layer comprising: a plurality of PCB elements arranged on the silkscreen layer; and a plurality of polarity markings arranged on the silkscreen layer, each polarity marking being formed from a first end line segment, a middle line segment perpendicularly connected to the first end line segment, and a second end line segment perpendicularly connected to the middle line segment, wherein each polarity marking indicates a polarity of a respective PCB element of the plurality of PCB elements and the plurality of polarity markings are the only polarity markings on the silkscreen layer.

In another aspect of the present invention, a method of eliminating an impedance requirement of a printed circuit board is disclosed, with the method comprising the steps of: setting an entire design at 50 ohms resistance; and setting a design rule for the pair to be matched at 0.010 inches.

These and other features, aspects and advantages of the present invention will become better understood with reference to the following drawings, description, and claims.

### BRIEF DESCRIPTION OF THE DRAWINGS

The following figures are included to illustrate certain aspects of the present disclosure and should not be viewed as exclusive embodiments. The subject matter disclosed is capable of considerable modifications, alterations, combinations, and equivalents in form and function, without departing from the scope of this disclosure.

FIG. 1 is a flow chart illustrating certain advantages of the present invention;

FIG. 2 is a schematic view of the prior art;

FIG. 3 is a schematic view of a first aspect of the present invention;

FIG. 4 is a schematic view of a first exemplary of a second aspect of the present invention;

FIG. 5 is a schematic view of a second exemplary design of the second aspect of the present invention;

FIG. 6 is a schematic view of a third exemplary design of the second aspect of the present invention; and

FIG. 7 is an exemplary impedance requirement chart that is eliminated as a result of the second aspect of the present invention.

### DETAILED DESCRIPTION OF THE INVENTION

The subject disclosure is described with reference to the drawings, wherein like reference numerals are used to refer to like elements throughout. In the following description, for purposes of explanation, numerous specific details are set forth in order to provide a thorough understanding of the present disclosure such that one skilled in the art will be enabled to make and use the present invention. It may be evident, however, that the present disclosure may be practiced without some of these specific details. For the purpose of clarity, technical material that is known in the technical fields related to the present invention has not been described in detail so that the present invention is not unnecessarily obscured

Broadly, embodiments of the present invention include a simplified method of marking the polarity on a PCB and a method of eliminating the need for impedance-controlled designs of a PCB.

The present invention permanently resolves a rampant problem in the PCB industry and reduces the time it takes to develop PCBs. These processes reduce the costs and cycle times of bare PCBs. It's a permanent solution to the inconsistency issue discussed above and has many benefits. For example, the strategy, discussed in greater detail below, works for every type of printed circuit board. It is also a very easy and simple solution to implement, requiring minimal time (e.g., a day or two) to update the parts library.

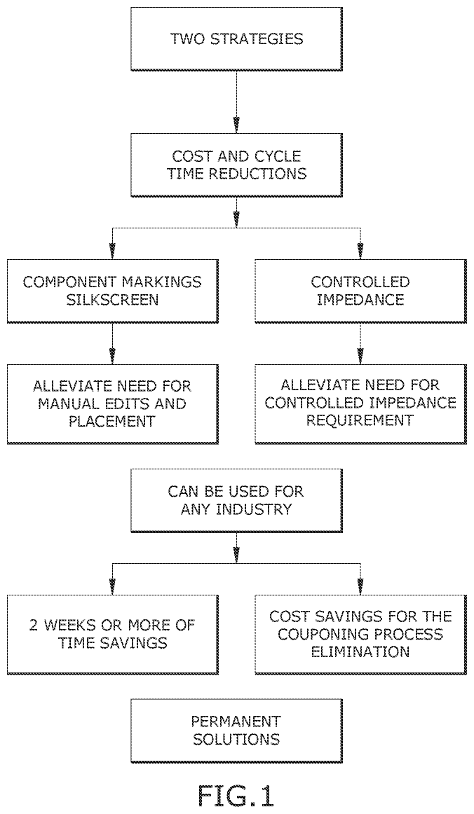

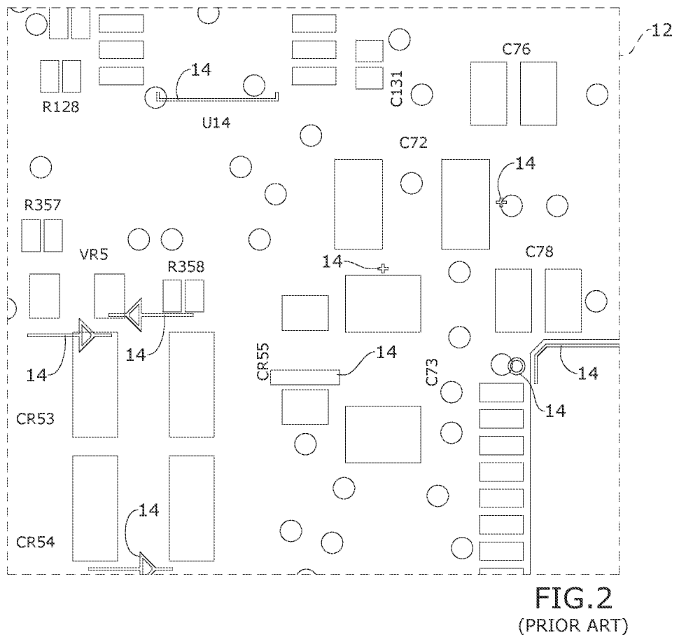

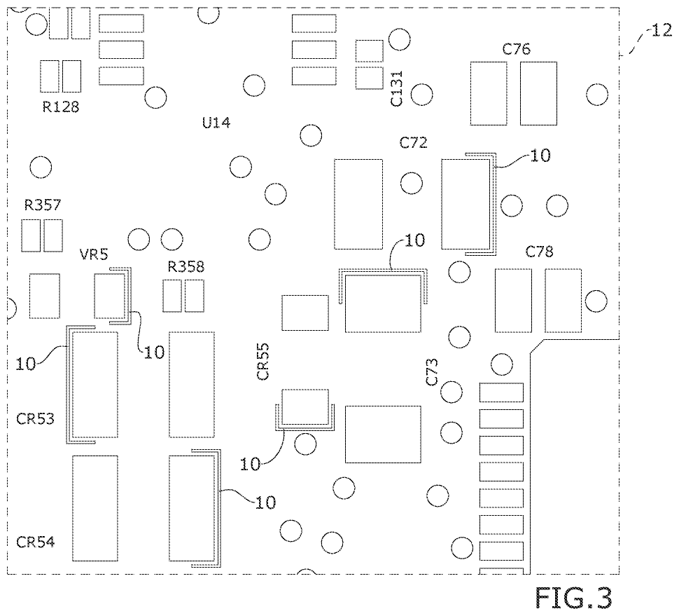

Referring now to FIGS. 1 and 3, the present invention provides, on a silkscreen layer of a PCB 12, new polarity markings 10 that are consistently used across the PCB 12. As seen in FIG. 3, all of the polarity markings 10 partially box in a respective PCB element (on three sides thereof) with three connected lines that are joined at a 90-degree angle to point to the positive side of the PCB element. This consistent, methodical approach is in stark contrast to the prior art, which varies in design with many different polarity markings 14. This new design also eliminates the need to move them because the markings are fixed. It is a simple, but highly effective solution, and saves an enormous amount of time not having to manipulate polarity markings and the potential rework to find the issues in test.

A second aspect of the present invention is the elimination of the need for impedance-controlled designs. Most of the time-controlled impedance designs were due to differential pair routing, which required tightly coupled traces. These pairs usually had different line widths in the design to meet this impedance, usually 100 ohm for tightly coupled pairs. The concept of “loosely couple” has been around for some time now and the present invention provides the process that alleviates the need for the impedance requirement. This process can be summarized as: a user sets up designs with a particular impedance and uses routing strategies to alleviate the need to specify a controlled impedance in the fabrication process. Below are three tested designs to demonstrate this process (i.e., the removal of controlled impedance designs).

Most, if not all, PCB design tools have the ability to design with a specific impedance for default traces. For example, 50 ohms is a very typical requirement. In accordance with the present invention, the entire design is set at 50 ohms and set a design rule for the pair to be matched at 0.010″ (it is noted that ″ is used interchangeably with the term ‘inches’ as appropriate). By doing so, someone practicing the present invention may thus be able to utilize the PCB tool's autotune feature to match the nets. Designs vary in many ways and for the instance of controlled impedance, the number of layers can affect the impedance so line widths will need to be adjusted to meet the 50 ohm rule. For instance, consider a scenario where layer 2 is closer to a plane layer than layer 6. Layer 2 line width will differ from the line width on layer 6 to meet the 50 ohms. One could be 0.005″ and the other may need to be 0.00525″. While this may seem trivial, it makes a substantial difference during the manufacturing process. Regarding matching the pair at 0.010″, the trace lengths are the same within the tolerance of 0.010″, So, by way of example, if one is 1″ the other needs to be 0.990″ to 1.010″.

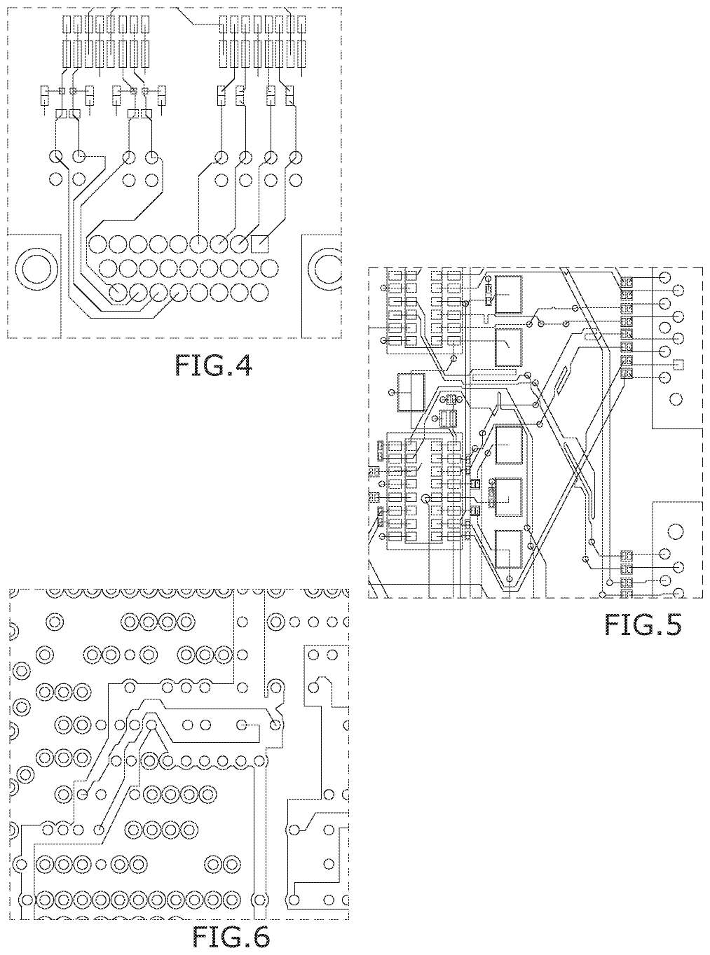

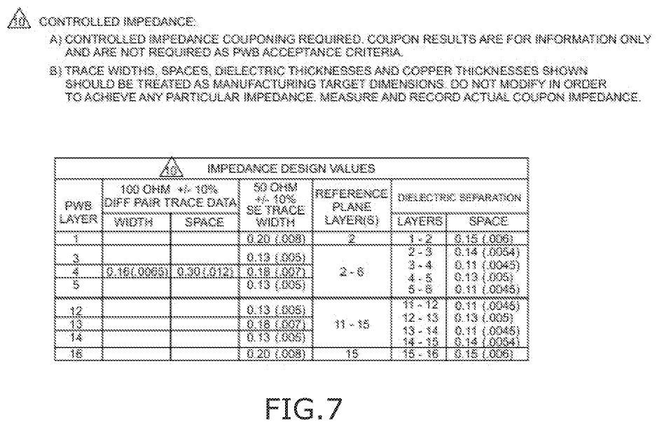

FIGS. 4-7 are illustrative examples of the aforementioned elimination of the need for impedance-controlled designs. As shown in FIG. 4, this loosely coupled design is clean and the tuning to match the pair is very easy. FIG. 4 illustrates RS422 lines. FIG. 5 depicts a design that used the auto-tune feature within the tool. The inventor does not personally care for auto-tuned nets for all the additional length it adds, but it's fast. FIG. 5 illustrates space wire nets. FIG. 6 depicts RTAX CLK nets. With further reference to FIG. 6, the need for the loosely coupled design practice on dense designs that provide no room to tightly couple, like in a BGA field. FIG. 7 is an impedance chart that is eliminated when the second aspect of the present invention is implemented.

All three aforementioned designs were manufactured and tested with no issues. No impedance table was needed on the FAB drawing. There was no need to set up differential pair traces. There was no tedious task of trying to tune a tightly coupled pair. There was no need for couponing and testing. Further, a PCB designer can set up the pair to be auto tuned as a matched length net.

Using the techniques described above (either individually or in conjunction), two or more weeks of cycle time can be reduced depending on testing failures and rework that is associated therewith. Further, hundreds to thousands of dollars in cost savings can be gained by not having to do extra couponing, testing, and time to prove a design meets the impedance specified on the FAB drawing. It can take up to 5 days to get through this process. On very rare occasions the process may damage the design and force a rebuild. Further, as those with skill in the art will appreciate, both aforementioned processes could be standalone (e.g., a design may not necessarily require controlled impedance) or used in conjunction with one another.

While one or more preferred embodiments are disclosed, many other implementations will occur to one of ordinary skill in the art and are all within the scope of the invention. Each of the various embodiments described above may be combined with other described embodiments in order to provide multiple features. Furthermore, while the foregoing describes a number of separate embodiments of the apparatus and method of the present invention, what has been described herein is merely illustrative of the application of the principles of the present invention. Other arrangements, methods, modifications, and substitutions by one of ordinary skill in the art are therefore also considered to be within the scope of the present invention, which is not to be limited except by the claims that follow.

While apparatuses and methods are described in terms of “comprising,” “containing,” or “including” various components or steps, the apparatuses and methods can also “consist essentially of” or “consist of” the various components and steps. All numbers and ranges disclosed above may vary by some amount.

Whenever a numerical range with a lower limit and an upper limit is disclosed, any number and any included range falling within the range is specifically disclosed. In particular, every range of values (of the form, “from about a to about b,” or, equivalently, “from approximately a to b,” or, equivalently, “from approximately a-b”) disclosed herein is to be understood to set forth every number and range encompassed within the broader range of values. Also, the terms in the claims have their plain, ordinary meaning unless otherwise explicitly and clearly defined by the patentee. Moreover, the indefinite articles “a” or “an,” as used in the claims, are defined herein to mean one or more than one of the elements that it introduces. If there is any conflict in the usages of a word or term in this specification and one or more patent or other documents that may be incorporated herein by reference, the definitions that are consistent with this specification should be adopted. Moreover, the use of directional terms such as above, below, upper, lower, upward, downward, left, right, and the like are used in relation to the illustrative embodiments as they are depicted in the figures, the upward or upper direction being toward the top of the corresponding figure and the downward or lower direction being toward the bottom of the corresponding figure.

As used herein, the phrase “at least one of” preceding a series of items, with the terms “and” or “or” to separate any of the items, modifies the list as a whole, rather than each member of the list (i.e., each item). The phrase “at least one of” allows a meaning that includes at least one of any one of the items, and/or at least one of any combination of the items, and/or at least one of each of the items. By way of example, the phrases “at least one of A, B, and C” or “at least one of A, B, or C” each refer to only A, only B, or only C; any combination of A, B, and C; and/or at least one of each of A, B, and C.

What is claimed is:

1. A silkscreen layer of a printed circuit board (PCB), the silkscreen layer comprising:
a plurality of PCB elements arranged on the silkscreen layer; and
a plurality of polarity markings arranged on the silkscreen layer, each polarity marking being formed from a first end line segment, a middle line segment perpendicularly connected to the first end line segment, and a second end line segment perpendicularly connected to the middle line segment,
wherein each polarity marking indicates a polarity of a respective PCB element of the plurality of PCB elements and the plurality of polarity markings are the only polarity markings on the silkscreen layer.

2. A method of eliminating an impedance requirement of a printed circuit board comprising the steps of:
providing the silkscreen layer of claim 1;
setting an entire design at 50 ohms resistance; and
setting a design rule for a differential pair routing to be matched at 0.010 inches.
